(19) United States
(12) Patent Application Publication
(10) Pub. No.: US 2026/0350941 A1
(43) Pub. Date: Nov. 5, 2026

(54) DEFORMATION CONTROL METHOD AND APPARATUS FOR VIRTUAL MODEL, AND ELECTRONIC DEVICE

(71) Applicant: NETEASE (HANGZHOU) NETWORK CO., LTD., Hangzhou, Zhejiang (CN)

(72) Inventor: Zhongyuan LIU, Hangzhou, Zhejiang (CN)

(73) Assignee: NETEASE (HANGZHOU) NETWORK CO., LTD., Hangzhou, Zhejiang (CN)

(21) Appl. No.: 19/118,820

(22) PCT Filed: Mar. 21, 2023
(86) PCT No.: PCT/CN2023/082823

§ 371 Date: Apr. 7, 2025

(30) Foreign Application Priority Data
Oct. 8, 2022 (CN) 202211222119.4

(51) Int. Cl. G06T 19/20; G06T 7/73; G06T 17/20

(52) U.S. Cl. CPC G06T 19/20; G06T 7/75; G06T 17/20; G06T 2200/04; G06T 2210/21; G06T 2219/2004; G06T 2219/2021

(57) ABSTRACT

A method for deformation control of a virtual model, includes: generating a target model and a particle model in coinciding with the target model in the virtual scene, particles in the particle model being connected through a virtual spring, a number of particles in the particle model being less than a number of mesh vertices in the target model, a mapping relationship being provided between a particle and a mesh vertex; in response to detecting a collision event, determining a first position of the particle after collision, based on a collision parameter of the collision and a deformation threshold of the virtual spring; determining a first rendering parameter for the mesh vertex based on the first position of the particle and the mapping relationship between the particle and the mesh vertex; and, obtaining a deformed target model by rendering the mesh vertex using the first rendering parameter.

### CROSS REFERENCE TO RELATED APPLICATIONS

The present application is a National Stage Application of International Application No. PCT/CN2023/082823 filed on Mar. 21, 2023, which is based upon and claims priority to Chinese Patent Application No. 202211222119.4 entitled “Method for deformation control of a virtual model, Apparatus, and Electronic device”, filed on Oct. 8, 2022, and the entire contents of both of which are incorporated herein by reference for all purposes.

### TECHNICAL FIELD

The present disclosure relates to the field of model rendering technology, and in particular, to a method for deformation control of a virtual model, an apparatus, and an electronic device.

### BACKGROUND

In a virtual scene, after a collision occurs to a model, a rigid collision body is usually used to simulate a state of the model after collision. When the rigid collision body is used to simulate the state of the model after collision, a position change and a posture change, such as rolling, rotating, or the like, may be generated after collision of the model. However, it is difficult to simulate the deformation of the model after collision, for example, deformation of the model, such as collapse, bulge, fragmentation, or the like, which results in a relatively lower realistic degree of this simulation manner. In the related art, finite element segmentation may also be performed on the model to obtain a large number of voxel sets. When a collision occurs to the model, the position of each voxel in the model is calculated according to various parameters such as collision strength and collision direction, so as to obtain a deformed model; however, the calculation amount in this manner is huge, a large amount of calculation time and computing resources are required, and it is difficult to be applied to a virtual scene rendered in real time.

### SUMMARY

According to an aspect of the present disclosure, there is provided a method for deformation control of a virtual model by some embodiments of the present disclosure, and the method includes: generating a target model located in a virtual scene and a particle model corresponding to the target model, where the particle model is provided in the virtual scene in a manner of coinciding with the target model, the particle model includes a plurality of particles, the plurality of particles are connected to each other through a virtual spring, a shape formed by the plurality of particles is matched with a shape of the target model, a number of particles in the particle model is less than a number of mesh vertices in the target model, and a preset mapping relationship is provided between a particle and a mesh vertex; in response to the particle model detecting a collision event, determining a first position of the particle in the particle model after the collision event occurs, based on a collision parameter of the collision event and a deformation threshold of the virtual spring; and, determining a first rendering parameter for the mesh vertex in the target model based on the first position of the particle in the particle model and the mapping relationship between the particle and the mesh vertex; and, obtaining a deformed target model by rendering the mesh vertex in the target model using the first rendering parameter.

According to an aspect of the present disclosure, there is further provided an electronic device, including a processor and a memory; the memory stores a machine-executable instruction executable by the processor; and the processor executes the machine-executable instruction to implement the foregoing method for deformation control of a virtual model.

According to an aspect of the present disclosure, there is further provided a non-transitory machine-readable storage medium, where the non-transitory machine-readable storage medium stores a machine-executable instruction, and when the machine-executable instruction is invoked and executed by a processor, the machine-executable instruction causes the processor to implement the foregoing method for deformation control of a virtual model.

### BRIEF DESCRIPTION OF THE DRAWINGS

FIG. 1 is a flowchart of a method for deformation control of a virtual model provided according to some embodiments of the present disclosure;

FIG. 2 is a schematic diagram of a particle model of a vehicle model provided according to some embodiments of the present disclosure;

FIG. 3 is a schematic diagram of a vehicle model provided according to some embodiments of the present disclosure;

FIG. 4 is a schematic structural diagram of an apparatus for deformation control of a virtual model provided according to some embodiments of the present disclosure;

FIG. 5 is a schematic diagram of an electronic device provided according to some embodiments of the present disclosure.

### DETAILED DESCRIPTION

In order to make the objectives, technical solutions, and advantages of the embodiments of the present disclosure clearer, the technical solutions of the present disclosure will be clearly and completely described below with reference to the accompanying drawings. Obviously, the described embodiments are a part of the embodiments of the present disclosure, not all of them.

All other embodiments obtained by those skilled in the art based on the embodiments of the present disclosure without creative efforts shall fall within the protection scope of the present disclosure.

In a game scene or other virtual scenes, the deformation simulation of the virtual model may be used to enrich the visual effect of the virtual model, thus improving the interaction experience of the user. However, most of the virtual models in the current virtual scene are non-deformable rigid bodies. The virtual model may be blocked by obstacles in the virtual scene, but the virtual model itself does not deform.

Taking the vehicle model in the game scene as an example, in the scene production stage, a rigid collision body may be configured for the vehicle model. When the game runs, if a collision occurs to the vehicle, and when physical simulation is performed on the vehicle model, the vehicle model is only involved in the rigid body simulation process to obtain the position and rotation of the rigid body, so as to render and control the position and rotation of the vehicle model, however, the deformation effect of the vehicle model caused by collision cannot be rendered.

In the related art, a finite element solution may be used in the deformation simulation of a virtual model. In this solution, finite element segmentation is performed on the virtual model to obtain a tetrahedron or hexahedral voxel set. When a collision occurs to the virtual model, an elastic matrix is assembled for each voxel in the model to obtain an elastic equation; by solving the elastic equation, the position of each voxel is obtained; and then, the deformation data of the virtual model is obtained. However, a large amount of voxels may usually be segmented from a virtual model; and, a large amount of computing resources and calculation time need to be consumed for performing calculation on each voxel, which is difficult to be applied to real-time rendering scenarios such as games.

Based on the foregoing, according to embodiments of the present disclosure, there is provided a method and apparatus for deformation control of a virtual model, and an electronic device, which may be applied to deformation control of a virtual model in a game scene or other types of virtual scenes, and may be particularly applied to real-time deformation rendering of a virtual model.

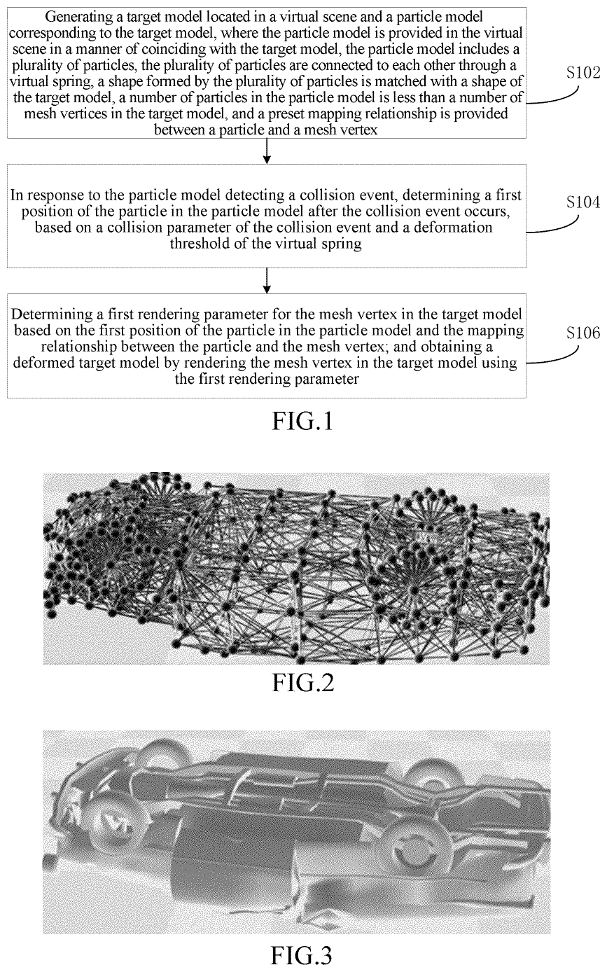

In order to facilitate understanding of the embodiments, the method for deformation control of a virtual model disclosed in the embodiments of the present disclosure is first described in detail. As shown in FIG. 1, the method for deformation control of a virtual model may be applied to a server or a terminal device, or may be applied to a cloud server. The method includes the following steps.

In step S102, a target model located in a virtual scene and a particle model corresponding to the target model are generated, where the particle model is provided in the virtual scene in a manner of coinciding with the target model, the particle model includes a plurality of particles, the plurality of particles are connected to each other through a virtual spring, the shape formed by the plurality of particles is matched with the shape of the target model, a number of particles in the particle model is less than a number of mesh vertices in the target model, and a preset mapping relationship is provided between a particle and a mesh vertex.

The target model may be various models with deformable attributes, such as a character model, a vehicle model, a model of a static object, and a model of a dynamic object. In the production process of the target model, in addition to production of the target model itself, a particle model matched with the target model needs to be produced. The sequence of production of the particle model and the target model is not limited. In the particle model, the particles are connected to each other through a virtual spring, one particle is usually connected to one or more surrounding particles, and the particle needs to be built with the virtual spring to obtain a relatively stable structure. Since the triangle is a relatively stable shape, generally, a triangle may be formed between the particle and the virtual spring. Therefore, the foregoing particle model may include a plurality of triangles.

In some embodiments, for a particle, it is usually determined, according to the shape of the particle model or the shape of the target model, that a virtual spring is provided between the particle and which particles. If a virtual spring is connected between the two particles, a certain elastic distance may be maintained between the two particles. The virtual spring may be implemented by a plastic spring, and the virtual spring may be provided with a deformation threshold and a fracture threshold. When a collision occurs to the particle model, all or part of the particles in the particle model are displaced. For a virtual spring, if two particles connected to the spring are displaced, or one of the particles is displaced, the virtual spring deforms, and the deformation may be specifically stretching or compressing.

When the deformation amount does not reach the deformation threshold, the virtual spring will rebound, for example, the virtual spring will rebound to the position where the virtual spring is not stretched or compressed. In this case, the positions of the two particles do not change. When the deformation amount reaches the deformation threshold, the virtual spring will not rebound.

In this case, the positions of the two particles will change, so as to simulate the deformation of the model. Further, when the deformation amount reaches the fracture threshold, it may be considered that the virtual spring is broken. In this case, the two particles may be separated from each other, so as to simulate the fragmentation of the model.

Due to the fact that the number of the mesh vertices in the target model is large, when a collision event occurs, if the position of the mesh vertex is directly calculated, huge calculation overhead is brought, which may result in lag of the scene picture, and it is difficult to be applied to a real-time rendering scene. In order to reduce the calculation amount, the number of particles in the particle model is less than the number of the mesh vertices in the target model. It can be understood that, the more the particles of the particle model, when a collision occurs, the more delicate and realistic the deformation of the target model is; however, the larger computing resource and computing duration are required to calculate the position of each particle and the rendering parameter for each mesh vertex in the target model.

The embodiment aims to realize real-time rendering of the simulated deformation. Based on this, the number of particles in the particle model is less than the number of mesh vertices in the target model. When a collision event occurs, the positions of a less number of particles are calculated, and then the rendering parameter for each mesh vertex in the target model is determined, so that the calculation amount and the calculation time may be reduced.

FIG. 2 and FIG. 3 serve as examples, where FIG. 2 shows a particle model of a vehicle model, and FIG. 3 shows an example that the target model is a vehicle model. The particle model includes a plurality of particles, and the particles are connected to each other through a virtual spring according to the shape of the vehicle model to obtain a particle model of a vehicle shape with a relatively stable structure. It may be known that the particle model and the target model are matched with each other in size and shape. In the virtual scene, the particle model and the target model are provided in a manner of coinciding with each other, but only the target model is displayed, and the particle model is used for detecting the collision event. Generally, the number of mesh vertices in the vehicle model is about 20000, and the number of particles in the particle model is about 900 totally.

In addition, in order to associate the particle model with the target model, a mapping relationship between the particle and the mesh vertex is preset. In the virtual scene, the rendering parameter for the mesh vertex in the target model is established based on the world coordinate system in the virtual scene, and the rendering parameter for the mesh vertex relative to the particle may be obtained according to the mapping relationship. After a collision occurs, the position of the particle changes, but the mapping relationship does not change. That is, the rendering parameter for the mesh vertex relative to the particle does not change. Based on this, the rendering parameter for the mesh vertex may be obtained after the position of the particle changes, so that the deformed target model is obtained by rendering.

In the running process of the virtual scene, the target model is located in the virtual scene.

Meanwhile, the particle model coincides with the target model, and is also provided in the virtual scene, but the particle model is not displayed. When the target model moves in the virtual scene, the particle model also moves simultaneously. That is, the particle model coincides with the target model in real time.

The particle model is used to detect a collision event. For example, the target model and the particle model may collide with obstacles and other models in the virtual scene. The size of the particle model may be the same as the size of the target model; or, the particle model may be slightly larger than the target model, and in this case, it may be more sensitive of the detection of the collision event; or, the particle model may be slightly smaller than the target model, and in this case, it may be more obtuse of the detection of the collision event.

In step S104, in response to the particle model detecting a collision event, a first position of the particle in the particle model after the collision event is determined based on the collision parameter of the collision event and the deformation threshold of the virtual spring.

The collision parameter of the collision event may include parameters such as a collision position of the target model, a collision direction of the target model, a collision strength of the target model, and a relative speed between models colliding with each other. According to these collision parameters, the displacement of each particle may be calculated by using an algorithm of Extended Position-Based Dynamics (XPBD) or other dynamics principles.

In addition, since a virtual spring is connected between the particles, the displacement of the particle may lead to deformation of the virtual spring. If the displacement is small, the deformation amount of the virtual spring may not exceed the deformation threshold; in this case, the virtual spring may rebound, and the first position of the particle is the same as the initial position before collision, or slightly changes. If the deformation of the virtual spring exceeds the deformation threshold, the virtual spring will not rebound, and the first position of the particle may be different from the initial position before the collision significantly.

In step S106, a first rendering parameter for the mesh vertex in the target model is determined based on the first position of the particle in the particle model and the mapping relationship between the particle and the mesh vertex; and, a deformed target model is obtained by rendering the mesh vertex in the target model using the first rendering parameter

After a collision occurs, the particle reaches the first position. Since there is a relatively fixed mapping relationship between the particle and the mesh vertex, the first rendering parameter for the mesh vertex after collision may be obtained based on the first position of the particle.

The first rendering parameter may include a position parameter, a normal parameter, a tangent parameter of the mesh vertex after collision, etc. Then, by rendering the mesh vertex in the target model using the first rendering parameter, the deformed target model caused by collision may be obtained.

According to the method for deformation control of a virtual model, a target model located in a virtual scene and a particle model corresponding to the target model are generated, where the particle model is provided in the virtual scene in a manner of coinciding with the target model; the particle model includes a plurality of particles, and the plurality of particles are connected to each other through a virtual spring; the shape formed by the plurality of particles is matched with the shape of the target model; the number of particles in the particle model is less than the number of mesh vertices in the target model; a preset mapping relationship is provided between a particle and a mesh vertex; in response to the particle model detecting a collision event, a first position of the particle in the particle model after the collision event occurs is determined based on a collision parameter of the collision event and a deformation threshold of the virtual spring; a first rendering parameter for the mesh vertex in the target model is determined based on the first position of the particle in the particle model and the mapping relationship between the particle and the mesh vertex; and, the deformed target model is obtained by rendering the mesh vertex in the target model using the first rendering parameter. In this manner, a particle model is provided for the target model, the particle model includes a less number of particles, the particles are connected to each other through the virtual spring, and the collision event is detected by the particle model; if the collision occurs, the displacement between the particles is calculated, and the rendering parameter for the target model after deformation is determined according to the deformation of the virtual spring, so as to obtain the deformed target model by rendering. In this manner, the calculation amount of deformation calculation is relatively less, the efficiency is higher, the deformation effect is vivid, and it is suitable for the virtual scene rendered in real time.

The manner of detecting a collision event is described below.

Specifically, in response to the target model being located in the virtual scene, it is detected whether a collision occurs to the particle by using the particles in the particle model; and if the collision occurs to at least one particle in the particle model, it is determined that a collision event is detected.

In this manner, a collision event is detected by the particle in the particle model. All or part of the particles in the particle model have a collision detection function. For example, a detection ray may be provided for these particles, and it may be detected whether the particle itself is in contact with or collide with other models in the scene by using the ray. When the target model is located in the virtual scene, these particles detect whether they collide with other models in real time or regularly. When the collision model in the virtual scene is small, it may only collide with one particle in the particle model, and in this case, the particle detects the collision event.

When the collision model is large, it may collide with a plurality of particles in the particle model, and in this case, the plurality of particles jointly detect the collision event.

A manner of determining the position of each particle in the particle model after a collision event occurs is described below.

Specifically, in response to the particle model detecting the collision event, the collision parameter of the collision event is obtained, where the collision parameter includes more than one of a target particle of the occurred collision, a collision direction, and a collision strength; based on the collision parameter, each particle in the particle model is controlled to be displaced, and a deformation amount of the virtual spring connected between the particles in the displacement process of the particle is monitored; and, the first position of the particle is determined based on the deformation amount and the deformation threshold.

It may be understood that the target particle where the collision occurs usually has a large displacement amount, and the target particle is connected to the surrounding particle through the virtual spring, thus the surrounding particle may also be displaced under the action of the virtual spring, and then other particles connected to the surrounding particle may also be displaced. In some embodiments, the displacement amount of each particle may be calculated by using an algorithm of XPBD or other dynamics principles. The collision direction may affect the range of particles that are displaced in the particle model, and the particle away from the collision direction may not be displaced, or only be displaced with a small amount. The collision strength may affect the displacement amount of the particle and the number of particles that are displaced. The greater the collision strength, the greater the displacement amount of the particle, and the larger the number of particles that are displaced.

According to collision parameters, the displacement of each particle is calculated based on the dynamics principle, and the particle is controlled to displace. The displacement of the particle may drive the connected virtual spring to deform. According to the nature of the spring, when the deformation amount of the spring does not exceed the deformation threshold, the virtual spring may rebound entirely or partially. When the deformation amount exceeds the deformation threshold, the virtual spring may not rebound. Therefore, after the collision occurs, the first position of the particle is related to the deformation threshold.

It should be noted that, after the collision occurs, the displacement of the particle and the deformation of the virtual spring affect each other. For example, the larger the displacement amount of the particle, the larger the deformation amount of the virtual spring; and when the deformation amount exceeds the deformation threshold, the position of the particle may not be restored to the initial position. Generally, the closer the particle to the target particle where the collision occurs, the larger the displacement amount, and the larger the deformation amount of the virtual spring connected to the target particle where the collision occurs or the virtual spring closer to the target particle.

In some embodiments, if the deformation amount does not exceed the deformation threshold of the virtual spring, the virtual spring is controlled to rebound, and the first position of the particle is determined based on the length of the rebound virtual spring. If the deformation amount exceeds the deformation threshold of the virtual spring, the length of the virtual spring after deformation is determined, and the first position of the particle is determined based on the length of the virtual spring after deformation. The virtual spring here is also referred to as a plastic spring, because compressing or stretching may cause that the spring yields and has permanent deformation. The deformation threshold may also be referred to as a plastic threshold. When the deformation amount of the virtual spring exceeds the deformation threshold, the static length of the virtual spring changes, and therefore, the position of the particle also changes permanently. The static length may be understood as the length of the virtual spring when no external force is applied.

When the deformation amount exceeds the deformation threshold, the position of the particle may change permanently, and in this case, the particle may drive the position of the model vertex in the target model to change, thus controlling the target model to deform.

Further, when the collision is severe, the target model may be locally broken or fragmented. In order to simulate the effect, in one manner, if the deformation amount exceeds the fracture threshold of the virtual spring, the virtual spring is removed to control the particles at the two ends of the virtual spring to be separated from each other to obtain the first position of the particle. The fracture threshold is typically greater than the aforementioned deformation threshold. Taking stretching as an example, the virtual spring is driven by the displacement of the particle to stretch, and a deformation amount is generated; in the continuous stretching process, the deformation amount reaches the deformation threshold; in the continuous stretching process, the deformation amount reaches the fracture threshold; and in this case, the virtual spring is broken. When the virtual spring is compressed, the virtual spring also has a deformation threshold and a fracture threshold. In the process that the virtual spring is compressed, the deformation amount may first reach the deformation threshold; and when the virtual spring continues to be compressed, the deformation amount may reach the fracture threshold.

When the virtual spring reaches the fracture threshold, in order to simulate the effect of the particle when the spring is broken, the virtual spring is removed in this case, and the particle is no longer connected to the virtual spring. Therefore, the movement of the particle is no longer affected by the virtual spring. In this case, the first position of the particle under the condition that the particle is not constrained by the virtual spring may also be calculated by using the foregoing related algorithm of dynamics principle.

In this manner, the effect that the target model is broken and fractured may be simulated under the condition that the collision is severe, for example, the effect that the vehicle door in the vehicle model falls off is simulated.

After the first position of the particle is obtained, the first position of each particle may be stored in a map. Since the number of particles is relatively less, the data amount of the map is also relatively less.

The embodiment aims to control the deformation of the target model by using the particle model. Therefore, in the production process of the target model, the mapping relationship between the particle and the mesh vertex needs to be set. The specific manner of setting the mapping relationship is provided below, which includes the following step 21 to step 24.

In step 21, the target model and the particle model are paced in a preset world coordinate system in a manner of coinciding with each other.

In this case, the mesh vertex in the target model and the particle in the particle model both have respective world coordinates.

In step 22, for the mesh vertex in the target model, a specified number of target particles is determined from the particle model, a local coordinate system is established based on the specified number of target particles, and a first conversion relationship between the local coordinate system and the world coordinate system is determined.

In order to associate the mesh vertex with the particle, the above step 22 may be performed for each mesh vertex in the target model. Specifically, a specified number of target particles may be determined from the periphery of the mesh vertex. The target particle is used to establish a local coordinate system to determine the relative relationship between the mesh vertex and the target particle by using the local coordinate system. The specified number of target particles may be determined according to requirements, for example, two, three, or other numbers.

In some embodiments, for the mesh vertices in the target model, Euclidean distances between the mesh vertex and at least part of particles in the particle model are calculated; a particle sequence is obtained by sorting the at least part of particles in an ascending order according to the Euclidean distances; and the first three particles in the particle sequence are determined as the target particles.

In some embodiments, for each mesh vertex, the Euclidean distance between the mesh vertex and each particle may be calculated. The smaller the Euclidean distance, the closer the particle is to the mesh vertex. When the local coordinate system is a three-dimensional coordinate system, three target particles need to be determined. Therefore, three particles with the smallest Euclidean distance are selected as the target particles for the current mesh vertex.

It may be understood that the local coordinate system usually includes a coordinate origin and a plurality of axial directions. The coordinate origin is usually a coordinate point in the world coordinate system, and based on the coordinate point, a conversion relationship between the origin of the local coordinate system and the origin of the world coordinate system may be obtained. In addition, the axial direction of the local coordinate system may be determined according to the relative position relationship between the plurality of target particles, and the relative position relationship between the target particles may be determined by using the difference vector between the coordinate points of the target particles in the world coordinate system. Therefore, the first conversion relationship may include the conversion relationship between the origin of the local coordinate system and the origin of the world coordinate system, and the conversion relationship for the axial direction.

In some embodiments, the local coordinate system may be established in the following manner: taking a first particle in the target particles as the origin of the local coordinate system; taking a connecting direction between the first particle and a second particle in the target particle as a first axial direction of the local coordinate system; taking a direction corresponding to a vector product of a connecting direction between a third particle in the target particles and the first particle and the first axial direction as a second axial direction of the local coordinate system; and, taking a direction perpendicular to both the first axial direction and the second axial direction as a third axial direction of the local coordinate system to obtain the local coordinate system.

As an example, the three target particles are represented as particle n0, particle n1, and particle n2, respectively, where the particle n0 is used as the origin of the local coordinate system. The first axial direction, the second axial direction, and the third axial direction are respectively an X-axis direction, a Y-axis direction and a Z-axis direction. Among them, the X-axis direction is represented as normalize (n1−n0), that is, a vector pointing from n0 to n1 is obtained by subtracting the coordinate value of the particle n0 in the world coordinate system from the coordinate value of the particle n1 in the world coordinate system, and the vector is normalized by using a normalize function to obtain a unit vector only indicating a direction for representing the X-axis direction.

Similarly, the Y-axis direction is represented as normalize (cross (n2−n0, X)); that is, a vector pointing from n0 to n2 is obtained by n2−n0, a vector product of the vector and the X-axis direction is obtained by calculating using a cross function, and then the vector product is normalized by using a normalize function to obtain the Y-axis direction. For the Z-axis direction, it is necessary to be perpendicular to the plane formed by the X-axis direction and the Y-axis direction, so as to determine the Z-axis direction.
Step 23, based on the first conversion relationship, a local rendering parameter is obtained by converting an initial rendering parameter of the mesh vertex in the world coordinate system into the local coordinate system, where the initial rendering parameter includes more than one of a position parameter, a normal parameter and a tangent parameter of the mesh vertex.

The initial rendering parameter here is used to determine the rendering manner of the mesh vertex, where the position parameter is used to determine which position in the world coordinate system the mesh vertex is rendered to, and the normal parameter and the tangent parameter are used to render the orientation of the mesh vertex, thus affecting the illumination effect or other rendering effects of the mesh vertex. The initial rendering parameter is defined in the world coordinate system, and in this step, the rendering parameter needs to be converted into the local coordinate system, so that the rendering parameter of the mesh vertex changes with the position of the particle after displacement of the particle, thus controlling the deformation effect of the target model.

The first conversion relationship may be represented in a form of a matrix or an inverse matrix.

The local rendering parameter in the local coordinate system may be obtained through multiplying the initial rendering parameter by the first conversion relationship.

In step 24, the mesh vertex, the target particles and the local rendering parameter are determined as the mapping relationship between the particle and the mesh vertex.

For each mesh vertex in the target model, target particles corresponding to the mesh vertex, a local coordinate system established by the target particles, and a first conversion relationship between the local coordinate system and the world coordinate system may be obtained, and then, the local rendering parameter in the local coordinate system may be obtained by converting the initial rendering parameter in the world coordinate system based on the first conversion relationship. Therefore, each mesh vertex is provided with target particles and a local rendering parameter, which are taken as the mapping relationship corresponding to the mesh vertex.

When the target model runs in the virtual scene and the collision event occurs, the first position of the particle in the particle model is determined, and the mapping relationship between the particle and the mesh vertex is also predetermined. In this case, the first rendering parameter for the mesh vertex in the world coordinate system may be obtained after the collision occurs, which is specifically implemented by the following step 31 to step 34.

In step 31, a specified number of target particles corresponding to the mesh vertex is obtained from the mapping relationship;

Since each mesh vertex in the target model is preset with a mapping relationship, for each mesh vertex, target particles may be obtained from the mapping relationship. It should be noted that the target particles corresponding to the adjacent mesh vertices may be the same or partially the same.

In step 32, a deformation coordinate system is established based on first positions of the specified number of target particles, and a second conversion relationship between the deformation coordinate system and a preset world coordinate system is determined, where the world coordinate system is established in the virtual scene where the target model and the particle model are located.

After the collision event occurs, the position of the target particle may change. The first position is the first position of the target particle after the collision event occurs. If the target particle is displaced in the collision process, the first position is different from the initial position of the target particle before the collision event occurs. If the target particle is not displaced in the collision process, the first position is the same as the initial position of the target particle before the collision event occurs.

The deformation coordinate system is established by using the target particles in the same way as the local coordinate system is established. Considering that the target particles may be displaced, the relative position between the target particles may also change. Based on this, the axial directions of the deformation coordinate system may be different from the axial directions of the local coordinate system, and the origin of the deformation coordinate system may be the same particle as the origin of the local coordinate system. For example, the particle n0 is used as the origin.

The second conversion relationship includes a conversion relationship between the origin of the deformation coordinate system and the origin of the world coordinate system, and further includes a conversion relationship of the axial directions. Since the relative position between the target particles may change after collision, the conversion relationship of the axial directions may be different from the conversion relationship corresponding to the local coordinate system.

In step 33, a local rendering parameter corresponding to the mesh vertex is obtained from the mapping relationship.

Here, the local rendering parameter indicates the rendering parameter for the mesh vertex relative to the particle, and is obtained by calculating according to the first conversion relationship corresponding to the local coordinate system. No matter how the position of the target particle changes, the local rendering parameter does not change.

In step 34, the first rendering parameter for the mesh vertex in the world coordinate system is determined based on the second conversion relationship and the local rendering parameter.

Since the relative position of the target particle in the world coordinate system changes, in order to obtain the rendering parameter for the mesh vertex in the world coordinate system after the collision event occurs, the local rendering parameter for the mesh vertex relative to the target particle needs to be converted again into the world coordinate system based on the second conversion relationship. In some embodiments, the local rendering parameter may be multiplied by the second conversion relationship, or the local rendering parameter may be multiplied by the inverse matrix of the second conversion relationship, to obtain the first rendering parameter. The deformation effect of the target model may be obtained by rendering in the virtual scene using the first rendering parameter.

When the target model is a vehicle model, the foregoing embodiments may implement that, after the vehicle model is deformed due to colliding with and obstacle in a game scene, a deformed vehicle model may be obtained by efficiently rendering in real time.

In the above embodiments, a plastic spring particle model is used as the particle module for simulating the deformation of the vehicle model, so that the rendering parameter for the model vertex may be efficiently updated, and the shape of the rendered model may be updated in the VertexShader. In some embodiments, the position of the particle after collision and deformation may be calculated in real time through the XPBD technology. In the stage that the VertexShader in the rendering pipeline is used, the position of the vertex may be rendered after the deformation is obtained by performing parallel interpolation on the GPU.

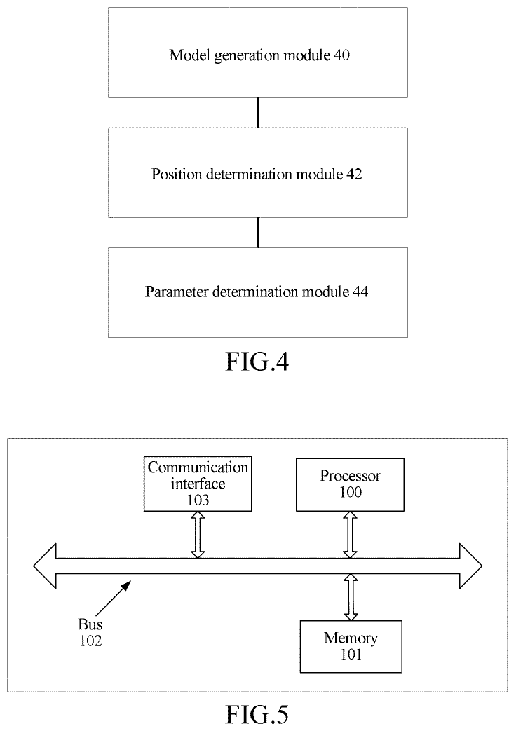

Corresponding to the foregoing method embodiments, referring to FIG. 4, FIG. 4 shows a schematic structural diagram of an apparatus for deformation control of a virtual model, and the apparatus includes a model generation module 40, a position determination module 42, and a parameter determination module 44.

The model generation module 40 is configured to generate a target model located in a virtual scene and a particle model corresponding to the target model, where the particle model is provided in the virtual scene in coincidence with the target model, the particle model includes a plurality of particles, and the plurality of particles are connected to each other through a virtual spring, a shape formed by the plurality of particles is matched with a shape of the target model, a number of particles in the particle model is less than a number of mesh vertices in the target model, and a preset mapping relationship is provided between a particle and a mesh vertex.

The position determination module 42 is configured to, in response to the particle model detecting a collision event, determine a first position of the particle in the particle model after the collision event occurs, based on a collision parameter of the collision event and a deformation threshold of the virtual spring.

The parameter determination module 44 is configured to, determine a first rendering parameter for the mesh vertex in the target model based on the first position of the particle in the particle model and the mapping relationship between the particle and the mesh vertex, and obtain a deformed target model by rendering the mesh vertex in the target model using the first rendering parameter.

According to the apparatus for deformation control of a virtual model, a target model located in a virtual scene and a particle model corresponding to the target model are generated, where the particle model is provided in the virtual scene in a manner of coinciding with the target model; the particle model includes a plurality of particles, and the plurality of particles are connected to each other through a virtual spring; the shape formed by the plurality of particles is matched with the shape of the target model; the number of particles in the particle model is less than the number of mesh vertices in the target model; a preset mapping relationship is provided between a particle and a mesh vertex; in response to the particle model detecting a collision event, a first position of the particle in the particle model after the collision event occurs is determined based on a collision parameter of the collision event and a deformation threshold of the virtual spring; a first rendering parameter for the mesh vertex in the target model is determined based on the first position of the particle in the particle model and the mapping relationship between the particle and the mesh vertex; and, the deformed target model is obtained by rendering the mesh vertex in the target model using the first rendering parameter.

In this manner, a particle model is provided for the target model, the particle model includes a less number of particles, the particles are connected to each other through the virtual spring, and the collision event is detected by the particle model; if the collision occurs, the displacement between the particles is calculated, and the rendering parameter for the target model after deformation is determined according to the deformation of the virtual spring, so as to obtain the deformed target model by rendering. In this manner, the calculation amount of deformation calculation is relatively less, the efficiency is higher, the deformation effect is vivid, and it is suitable for the virtual scene rendered in real time.

In some embodiments, the apparatus for deformation control of the virtual model further includes a collision detection module, configured to: in response to the target model being located in the virtual scene, detect, by the particle in the particle model, whether a collision occurs to the particle; and, if the collision occurs to at least one particle in the particle model, determine that the collision event is detected.

In some embodiments, the position determination module is further configured to: in response to the particle model detecting the collision event, obtain the collision parameter of the collision event, where the collision parameter includes more than one of a target particle of the occurred collision, a collision direction, and a collision strength; control, based on the collision parameter, each particle in the particle model to be displaced, and monitor a deformation amount of the virtual spring connected between the particles in a displacement process of the particle; and, determine the first position of the particle based on the deformation amount and the deformation threshold.

In some embodiments, the position determination module is further configured to: if the deformation amount does not exceed the deformation threshold of the virtual spring, control the virtual spring to rebound, and determine the first position of the particle based on a length of the virtual spring after rebound; or, if the deformation amount exceeds the deformation threshold of the virtual spring, determine a length of the virtual spring after deformation, and determine the first position of the particle based on the length of the virtual spring after deformation.

In some embodiments, the apparatus for deformation control of the virtual model further includes a removal module, configured to: if the deformation amount exceeds a fracture threshold of the virtual spring, remove the virtual spring to control particles at two ends of the virtual spring to be separated from each other to obtain the first position of the particle.

In some embodiments, the apparatus for deformation control of the virtual model further includes a mapping relationship determination module, configured to: place the target model and the particle model in a preset world coordinate system in a manner of coinciding with each other; for the mesh vertex in the target model, determine a specified number of target particles from the particle model, establish a local coordinate system based on the specified number of target particles, and determine a first conversion relationship between the local coordinate system and the world coordinate system; obtain a local rendering parameter by converting an initial rendering parameter for the mesh vertex in the world coordinate system into the local coordinate system based on the first conversion relationship, where the initial rendering parameter includes more than one of a position parameter, a normal parameter, and a tangent parameter for the mesh vertex; and determine the mesh vertex, the target particles and the local rendering parameter as the mapping relationship between the particle and the mesh vertex.

In some embodiments, the mapping relationship determination module is further configured to: for the mesh vertex in the target model, calculate Euclidean distances between the mesh vertex and at least part of particles in the particle model; obtain a particle sequence by sorting the at least part of particles in an ascending order according to the Euclidean distances; and determine first three particles in the particle sequence as the target particles.

In some embodiments, the mapping relationship determination module is configured to: take a first particle in the target particles as an origin of the local coordinate system; take a connecting direction between the first particle and a second particle in the target particles as a first axial direction of the local coordinate system; take a direction corresponding to a vector product of a connecting direction between a third particle in the target particles and the first particle and the first axial direction, as a second axial direction of the local coordinate system; and obtain the local coordinate system by taking a direction perpendicular to both the first axial direction and the second axial direction as a third axial direction of the local coordinate system.

In some embodiments, the parameter determination module is further configured to: obtain a specified number of target particles corresponding to the mesh vertex from the mapping relationship; establish a deformation coordinate system based on first positions of the specified number of target particles, and determine a second conversion relationship between the deformation coordinate system and a preset world coordinate system, where the world coordinate system is established in the virtual scene where the target model and the particle model are located; obtain a local rendering parameter corresponding to the mesh vertex from the mapping relationship; and, determine the first rendering parameter for the mesh vertex in the world coordinate system based on the second conversion relationship and the local rendering parameter.

According to some embodiments, there is further provided an electronic device, including a processor and a memory, where the memory stores a machine-executable instruction executable by the processor, and the processor executes the machine-executable instruction to implement the method for deformation control of a virtual model. The electronic device may be a server, or may be a touch terminal device.

Referring to FIG. 5, the electronic device includes a processor 100 and a memory 101, where the memory 101 stores a machine-executable instruction executable by the processor 100, and the processor 100 executes the machine-executable instruction to implement the method for deformation control of a virtual model.

Furthermore, the electronic device shown in FIG. 5 further includes a bus 102 and a communication interface 103. The processor 100, the communication interface 103, and the memory 101 are connected by using the bus 102.

Among them, the memory 101 may include a high-speed random access memory (RAM), or may further include a non-volatile memory, for example, at least one magnetic disk memory.

The communication connection between the system network element and at least one other network element may be implemented by using at least one communication interface 103 (which may be wired or wireless), where the Internet, a wide area network, a local network, a metropolitan area network, or the like, may be used. The bus 102 may be an ISA bus, a PCI bus, an EISA bus, or the like. The bus may be classified into an address bus, a data bus, a control bus, or the like. For ease of representation, only one bidirectional arrow is used to represent the bus in FIG. 5, but this does not mean that there is only one bus or one type of bus.

The processor 100 may be an integrated circuit chip, and has a signal processing capability. In an implementation process, steps of the foregoing method may be completed by using an integrated logic circuit of hardware in the processor 100 or an instruction in a form of software.

The processor 100 may be a general-purpose processor, including a Central Processing Unit (CPU), a Network Processor (NP), or the like. Alternatively, the processor 100 may be a Digital Signal Processor (DSP), an Application Specific Integrated Circuit (ASIC), a Field-Programmable Gate Array (FPGA) or another programmable logic device, a discrete gate or transistor logic device, or a discrete hardware component. The processor 100 may be used to implement or perform the methods, steps, and logical block diagrams disclosed in the embodiments of the present disclosure. The general-purpose processor may be a microprocessor, or the processor may be any conventional processor, etc. The steps of the methods disclosed with reference to the embodiments of the present disclosure may be directly performed by a hardware decoding processor, or may be performed and completed by using a combination of the hardware module and the software module in a decoding processor. The software module may be located in a proven storage medium in the art, such as a random access memory, a flash memory, a read-only memory, a programmable read-only memory, an electrically erasable programmable memory, or a register. The storage medium is located in the memory 101, and the processor 100 reads information in the memory 101 and completes the steps of the method in the foregoing embodiments in combination with hardware of the processor 100.

The processor in the electronic device may implement the following operations in the method for deformation control of a virtual model by executing a machine-executable instruction.

A target model located in the virtual scene and a particle model corresponding to the target model are generated, where the particle model is provided in the virtual scene in a manner of coinciding with the target model; the particle model includes a plurality of particles, and the plurality of particles are connected to each other through a virtual spring; the shape formed by the plurality of particles is matched with a shape of the target model; the number of particles in the particle model is less than the number of mesh vertices in the target model; and a preset mapping relationship is provided between a particle and a mesh vertex. In response to the particle model detecting a collision event, a first position of a particle in the particle model after the collision event is determined based on a collision parameter of the collision event and a deformation threshold of the virtual spring. A first rendering parameter for the mesh vertex in the target model is determined based on the first position of the particle in the particle model and the mapping relationship between the particle and the mesh vertex. A deformed target model is obtained by rendering the mesh vertex in the target model using the first rendering parameter.

In some embodiments, in response to the target model being located in the virtual scene, it is detected, by the particle in the particle model, whether a collision occurs to the particle; and if the collision occurs to at least one particle in the particle model, it is determined that the collision event is detected.

In some embodiments, in response to the particle model detecting the collision event, the collision parameter of the collision event is obtained, where the collision parameter includes more than one of a target particle of the occurred collision, a collision direction, and a collision strength; Based on the collision parameter, each particle in the particle model is controlled to be displaced, and a deformation amount of a virtual spring connected between the particles is monitored in the displacement process of the particle. The first position of the particle is determined based on the deformation amount and the deformation threshold.

In some embodiments, if the deformation amount does not exceed the deformation threshold of the virtual spring, the virtual spring is controlled to rebound, and the first position of the particle is determined based on the length of the virtual spring after rebound. If the deformation amount exceeds the deformation threshold of the virtual spring, the length of the virtual spring after deformation is determined, and the first position of the particle is determined based on the length of the virtual spring after deformation.

In some embodiments, if the deformation amount exceeds a fracture threshold of the virtual spring, the virtual spring is removed to control the particles at two ends of the virtual spring to be separated from each other to obtain the first position of the particle.

In some embodiments, the mapping relationship between the particle and the mesh vertex is obtained in the following manner: placing the target model and the particle model in a preset world coordinate system in a manner of coinciding with each other; for the mesh vertex in the target model, determining a specified number of target particles from the particle model, establishing a local coordinate system based on the specified number of target particles, and determining a first conversion relationship between the local coordinate system and the world coordinate system; obtaining a local rendering parameter by converting an initial rendering parameter for the mesh vertex in the world coordinate system into the local coordinate system based on the first conversion relationship, where the initial rendering parameter includes more than one of a position parameter, a normal parameter, and a tangent parameter for the mesh vertex; and determining the mesh vertex, the target particles, and the local rendering parameter as the mapping relationship between the particle and the mesh vertex.

In some embodiments, for the mesh vertex in the target model, Euclidean distances between the mesh vertex and at least part of particles in the particle model are calculated; a particle sequence is obtained by sorting the at least part of particles in an ascending order according to the Euclidean distances; and, first three particles in the particle sequence are determined as the target particles.

In some embodiments, a first particle in the target particles is taken as the origin of the local coordinate system; a connecting direction between the first particle and a second particle in the target particles is taken as the first axial direction of the local coordinate system; a direction corresponding to a vector product of a connecting direction between a third particle in the target particles and the first particle and the first axial direction is taken as the second axial direction of the local coordinate system; and, the local coordinate system is obtained by taking a direction perpendicular to both the first axial direction and the second axial direction as the third axial direction of the local coordinate system.

In some embodiments, a specified number of target particles corresponding to the mesh vertex is obtained from the mapping relationship; a deformation coordinate system is established based on first positions of the specified number of target particles, and a second conversion relationship between the deformation coordinate system and a preset world coordinate system is determined, where the world coordinate system is established in the virtual scene where the target model and the particle model are located; a local rendering parameter corresponding to the mesh vertex is obtained from the mapping relationship; and, the first rendering parameter for the mesh vertex in the world coordinate system is determined based on the second conversion relationship and the local rendering parameter.

In this manner, a particle model is provided for the target model, the particle model includes a less number of particles, the particles are connected to each other through the virtual spring, and the collision event is detected by the particle model; if the collision occurs, the displacement between the particles is calculated, and the rendering parameter for the target model after deformation is determined according to the deformation of the virtual spring, so as to obtain the deformed target model by rendering. In this manner, the calculation amount of deformation calculation is relatively less, the efficiency is higher, the deformation effect is vivid, and it is suitable for the virtual scene rendered in real time.

According to some embodiments, there is further provided a non-transitory machine-readable storage medium, where the non-transitory machine-readable storage medium stores a machine-executable instruction, and when the machine-executable instruction is invoked and executed by a processor, the machine-executable instruction causes the processor to implement the method for deformation control of a virtual model.

The machine-executable instruction is stored in the non-transitory machine-readable storage medium, and the following operations in the method for deformation control of a virtual model may be implemented by executing the machine-executable instruction.

A target model located in the virtual scene and a particle model corresponding to the target model are generated, where the particle model is provided in the virtual scene in a manner of coinciding with the target model; the particle model includes a plurality of particles, and the plurality of particles are connected to each other through a virtual spring; the shape formed by the plurality of particles is matched with a shape of the target model; the number of particles in the particle model is less than the number of mesh vertices in the target model; and a preset mapping relationship is provided between a particle and a mesh vertex. In response to the particle model detecting a collision event, a first position of a particle in the particle model after the collision event is determined based on a collision parameter of the collision event and a deformation threshold of the virtual spring. A first rendering parameter for the mesh vertex in the target model is determined based on the first position of the particle in the particle model and the mapping relationship between the particle and the mesh vertex. A deformed target model is obtained by rendering the mesh vertex in the target model using the first rendering parameter.

In some embodiments, in response to the target model being located in the virtual scene, it is detected, by the particle in the particle model, whether a collision occurs to the particle; and if the collision occurs to at least one particle in the particle model, it is determined that the collision event is detected.

In some embodiments, in response to the particle model detecting the collision event, the collision parameter of the collision event is obtained, where the collision parameter includes more than one of a target particle of the occurred collision, a collision direction, and a collision strength; Based on the collision parameter, each particle in the particle model is controlled to be displaced, and a deformation amount of the virtual spring connected between the particles is monitored in the displacement process of the particle. The first position of the particle is determined based on the deformation amount and the deformation threshold.

In some embodiments, if the deformation amount does not exceed the deformation threshold of the virtual spring, the virtual spring is controlled to rebound, and the first position of the particle is determined based on the length of the virtual spring after rebound. If the deformation amount exceeds the deformation threshold of the virtual spring, the length of the virtual spring after deformation is determined, and the first position of the particle is determined based on the length of the virtual spring after deformation.

In some embodiments, if the deformation amount exceeds a fracture threshold of the virtual spring, the virtual spring is removed to control the particles at two ends of the virtual spring to be separated from each other to obtain the first position of the particle.

In some embodiments, the mapping relationship between the particle and the mesh vertex is obtained in the following manner: placing the target model and the particle model in a preset world coordinate system in a manner of coinciding with each other; for the mesh vertex in the target model, determining a specified number of target particles from the particle model, establishing a local coordinate system based on the specified number of target particles, and determining a first conversion relationship between the local coordinate system and the world coordinate system; obtaining a local rendering parameter by converting an initial rendering parameter for the mesh vertex in the world coordinate system into the local coordinate system based on the first conversion relationship, where the initial rendering parameter includes more than one of a position parameter, a normal parameter, and a tangent parameter for the mesh vertex; and determining the mesh vertex, the target particles, and the local rendering parameter as the mapping relationship between the particle and the mesh vertex.

In some embodiments, for the mesh vertex in the target model, Euclidean distances between the mesh vertex and at least part of particles in the particle model are calculated; a particle sequence is obtained by sorting the at least part of particles in an ascending order according to the Euclidean distances; and, first three particles in the particle sequence are determined as the target particles.

In some embodiments, a first particle in the target particles is taken as the origin of the local coordinate system; a connecting direction between the first particle and a second particle in the target particles is taken as the first axial direction of the local coordinate system; a direction corresponding to a vector product of a connecting direction between a third particle in the target particles and the first particle and the first axial direction is taken as the second axial direction of the local coordinate system; and, the local coordinate system is obtained by taking a direction perpendicular to both the first axial direction and the second axial direction as the third axial direction of the local coordinate system.

In some embodiments, a specified number of target particles corresponding to the mesh vertex is obtained from the mapping relationship; a deformation coordinate system is established based on first positions of the specified number of target particles, and a second conversion relationship between the deformation coordinate system and a preset world coordinate system is determined, where the world coordinate system is established in the virtual scene where the target model and the particle model are located; a local rendering parameter corresponding to the mesh vertex is obtained from the mapping relationship; and, the first rendering parameter for the mesh vertex in the world coordinate system is determined based on the second conversion relationship and the local rendering parameter.

In this manner, a particle model is provided for the target model, the particle model includes a less number of particles, the particles are connected to each other through the virtual spring, and the collision event is detected by the particle model; if the collision occurs, the displacement between the particles is calculated, and the rendering parameter for the target model after deformation is determined according to the deformation of the virtual spring, so as to obtain the deformed target model by rendering. In this manner, the calculation amount of deformation calculation is relatively less, the efficiency is higher, the deformation effect is vivid, and it is suitable for the virtual scene rendered in real time.

The computer program product of the method and apparatus for deformation control of a virtual model and the electronic device provided in the embodiments of the present disclosure include a computer-readable storage medium storing a program code, and an instruction included in the program code may be used to perform the method described in the foregoing method embodiments. For specific implementation, reference may be made to the method embodiments, and details are not described here again.

It may be clearly understood by those skilled in the art that, for the purpose of convenient and brief description, for the detailed working process of the foregoing system and apparatus, reference may be made to the corresponding process in the foregoing method embodiments, and details are not described here again.

In addition, in the description of the embodiments of the present disclosure, unless expressly specified and limited otherwise, the terms “mounted”, “connected” and “connecting” should be understood in a broad sense. For example, it may be a fixed connection, a detachable connection, or an integrated connection; it may be a mechanical connection or an electrical connection; or, it may be a direct connection, or may be an indirect connection by using an intermediate medium, or may be an internal communication between two elements. For those skilled in the art, the specific meanings of the above terms in the present disclosure may be understood according to specific situations.

When the functions are implemented in the form of a software functional unit and sold or used as an independent product, the functions may be stored in a computer-readable storage medium.

Based on such understanding, the technical solution of the present disclosure essentially, or the part of the technical solution that contributes to the related art, or a part of the technical solution may be embodied in the form of a software product. The computer software product is stored in a storage medium, and includes several instructions for causing a computer device (which may be a personal computer, a server, or a network device, etc.) to perform all or part of the steps of the methods described in the embodiments of the present disclosure. The foregoing storage medium includes any medium that may store a program code, such as a USB flash drive, a removable hard disk, a read-only memory (ROM), a random access memory (RAM), a magnetic disk, or an optical disk.

In the description of the present disclosure, it should be noted that the orientation or position relationship indicated by the terms “center”, “upper”, “lower”, “left”, “right”, “vertical”, “horizontal”, “inner”, “outer” or the like is based on the orientation or position relationship shown in the accompanying drawings, which is only for the convenience of describing the present disclosure and simplifying the description, and does not indicate or imply that the device or element referred to is required to have a specific orientation and be constructed and operated in a specific orientation, and therefore cannot be understood as a limitation to the present disclosure. In addition, the terms “first”, “second” and “third” are used for descriptive purposes only and cannot be understood as indicating or implying the relative importance.

Finally, it should be noted that, the above embodiments are only specific implementations of the present disclosure to illustrate the technical solutions of the present disclosure but not limitations of the present disclosure, and the protection scope of the present disclosure is not limited to this. Although the present disclosure is described in detail with reference to the foregoing embodiments, those skilled in the art should understand that those skilled in the art may still modify the technical solutions described in the foregoing embodiments, or easily think of changes, or equivalently replace some of the technical features in the present disclosure, within the technical scope disclosed in the present disclosure. These modifications, changes, or replacements do not cause the corresponding technical solutions to depart from the spirit and scope of the technical solutions of the embodiments of the present disclosure, and should all be covered within the protection scope of the present disclosure. Therefore, the protection scope of the present disclosure shall be subject to the protection scope of the claims.

1. A method for deformation control of a virtual model, comprising:
generating a target model located in a virtual scene and a particle model corresponding to the target model, wherein the particle model is provided in the virtual scene in a manner of coinciding with the target model, the particle model comprises a plurality of particles, the plurality of particles are connected to each other through a virtual spring, a shape formed by the plurality of particles is matched with a shape of the target model, a number of particles in the particle model is less than a number of mesh vertices in the target model, and a preset mapping relationship is provided between a particle and a mesh vertex;
in response to the particle model detecting a collision event, determining a first position of the particle in the particle model after the collision event occurs, based on a collision parameter of the collision event and a deformation threshold of the virtual spring; and
determining a first rendering parameter for the mesh vertex in the target model based on the first position of the particle in the particle model and the mapping relationship between the particle and the mesh vertex; and, obtaining a deformed target model by rendering the mesh vertex in the target model using the first rendering parameter.

2. The method according to claim 1, further comprising:
in response to the target model being located in the virtual scene, detecting, by the particle in the particle model, whether a collision occurs to the particle; and
in response to determining that the collision occurs to at least one particle in the particle model, determining that the collision event is detected.

3. The method according to claim 1, wherein determining the first position of the particle in the particle model after the collision event occurs based on the collision parameter of the collision event and the deformation threshold of the virtual spring, comprises:
in response to the particle model detecting the collision event, obtaining the collision parameter of the collision event, wherein the collision parameter comprises more than one of a target particle of the occurred collision, a collision direction, and a collision strength;
controlling, based on the collision parameter, each particle in the particle model to be displaced, and monitoring a deformation amount of the virtual spring connected between the particles in a displacement process of the particle; and
determining the first position of the particle based on the deformation amount and the deformation threshold.

4. The method according to claim 3, wherein determining the first position of the particle based on the deformation amount and the deformation threshold comprises:
in response to determining that the deformation amount does not exceed the deformation threshold of the virtual spring, controlling the virtual spring to rebound, and determining the first position of the particle based on a length of the virtual spring after rebound; or
in response to determining that the deformation amount of the virtual spring exceeds the deformation threshold of the virtual spring, determining a length of the virtual spring after deformation, and determining the first position of the particle based on the length of the virtual spring after deformation.

5. The method according to claim 3, further comprising:
in response to determining that the deformation amount exceeds a fracture threshold of the virtual spring, removing the virtual spring to control particles at two ends of the virtual spring to be separated from each other to obtain the first position of the particle.

6. The method according to claim 1, wherein obtaining the mapping relationship between the particle and the mesh vertex comprising:
placing the target model and the particle model in a preset world coordinate system in a manner of coinciding with each other;
for the mesh vertex in the target model, determining a specified number of target particles from the particle model, establishing a local coordinate system based on the specified number of target particles, and determining a first conversion relationship between the local coordinate system and the world coordinate system;
obtaining a local rendering parameter by converting an initial rendering parameter for the mesh vertex in the world coordinate system into the local coordinate system based on the first conversion relationship, wherein the initial rendering parameter comprises more than one of a position parameter, a normal parameter, and a tangent parameter for the mesh vertex; and
determining the mesh vertex, the target particles, and the local rendering parameter as the mapping relationship between the particle and the mesh vertex.

7. The method according to claim 6, wherein determining the specified number of target particles from the particle model, comprises:
for the mesh vertex in the target model, calculating Euclidean distances between the mesh vertex and at least part of particles in the particle model; and
obtaining a particle sequence by sorting the at least part of particles in an ascending order according to the Euclidean distances, and determining first three particles in the particle sequence as the target particles.

8. The method according to claim 6, wherein establishing the local coordinate system based on the specified number of target particles comprises:
taking a first particle in the target particles as an origin of the local coordinate system;
taking a connecting direction between the first particle and a second particle in the target particles as a first axial direction of the local coordinate system;
taking a direction corresponding to a vector product of a connecting direction between a third particle in the target particles and the first particle and the first axial direction as a second axial direction of the local coordinate system; and
obtaining the local coordinate system by taking a direction perpendicular to both the first axial direction and the second axial direction as a third axial direction of the local coordinate system.

9. The method according to claim 1, wherein determining the first rendering parameter for the mesh vertex in the target model based on the first position of the particle in the particle model and the mapping relationship between the particle and the mesh vertex comprises:
obtaining a specified number of target particles corresponding to the mesh vertex from the mapping relationship;
establishing a deformation coordinate system based on first positions of the specified number of target particles, and determining a second conversion relationship between the deformation coordinate system and a preset world coordinate system, wherein the world coordinate system is established in the virtual scene where the target model and the particle model are located;
obtaining a local rendering parameter corresponding to the mesh vertex from the mapping relationship; and
determining the first rendering parameter for the mesh vertex in the world coordinate system based on the second conversion relationship and the local rendering parameter.

10. (canceled)

11. An electronic device, comprising a processor and a memory, wherein the memory stores a machine-executable instruction executable by the processor, and the processor executes the machine-executable instruction to implement a method for deformation control of a virtual model, wherein the method comprises:
generating a target model located in a virtual scene and a particle model corresponding to the target model, wherein the particle model is provided in the virtual scene in a manner of coinciding with the target model, the particle model comprises a plurality of particles, the plurality of particles are connected to each other through a virtual spring, a shape formed by the plurality of particles is matched with a shape of the target model, a number of particles in the particle model is less than a number of mesh vertices in the target model, and a preset mapping relationship is provided between a particle and a mesh vertex;
in response to the particle model detecting a collision event, determining a first position of the particle in the particle model after the collision event occurs, based on a collision parameter of the collision event and a deformation threshold of the virtual spring; and
determining a first rendering parameter for the mesh vertex in the target model based on the first position of the particle in the particle model and the mapping relationship between the particle and the mesh vertex; and, obtaining a deformed target model by rendering the mesh vertex in the target model using the first rendering parameter.

12. A non-transitory machine-readable storage medium, wherein the non-transitory machine-readable storage medium stores a machine-executable instruction, and when the machine-executable instruction is invoked and executed by a processor, the machine-executable instruction causes the processor to implement a method for deformation control of a virtual model, wherein the method comprises:
generating a target model located in a virtual scene and a particle model corresponding to the target model, wherein the particle model is provided in the virtual scene in a manner of coinciding with the target model. the particle model comprises a plurality of particles, the plurality of particles are connected to each other through a virtual spring, a shape formed by the plurality of particles is matched with a shape of the target model, a number of particles in the particle model is less than a number of mesh vertices in the target model, and a preset mapping relationship is provided between a particle and a mesh vertex;
in response to the particle model detecting a collision event, determining a first position of the particle in the particle model after the collision event occurs, based on a collision parameter of the collision event and a deformation threshold of the virtual spring; and
determining a first rendering parameter for the mesh vertex in the target model based on the first position of the particle in the particle model and the mapping relationship between the particle and the mesh vertex; and, obtaining a deformed target model by rendering the mesh vertex in the target model using the first rendering parameter.

13. The electronic device according to claim 11, wherein the method further comprises:
in response to the target model being located in the virtual scene, detecting, by the particle in the particle model, whether a collision occurs to the particle; and
in response to determining that the collision occurs to at least one particle in the particle model, determining that the collision event is detected.

14. The electronic device according to claim 11, wherein determining the first position of the particle in the particle model after the collision event occurs based on the collision parameter of the collision event and the deformation threshold of the virtual spring, comprises:
in response to the particle model detecting the collision event, obtaining the collision parameter of the collision event, wherein the collision parameter comprises more than one of a target particle of the occurred collision, a collision direction, and a collision strength;
controlling, based on the collision parameter, each particle in the particle model to be displaced, and monitoring a deformation amount of the virtual spring connected between the particles in a displacement process of the particle; and
determining the first position of the particle based on the deformation amount and the deformation threshold.

15. The electronic device according to claim 14, wherein determining the first position of the particle based on the deformation amount and the deformation threshold comprises:
in response to determining that the deformation amount does not exceed the deformation threshold of the virtual spring, controlling the virtual spring to rebound, and determining the first position of the particle based on a length of the virtual spring after rebound; or
in response to determining that the deformation amount of the virtual spring exceeds the deformation threshold of the virtual spring, determining a length of the virtual spring after deformation, and determining the first position of the particle based on the length of the virtual spring after deformation.

16. The electronic device according to claim 14, wherein the method further comprises:
in response to determining that the deformation amount exceeds a fracture threshold of the virtual spring, removing the virtual spring to control particles at two ends of the virtual spring to be separated from each other to obtain the first position of the particle.

17. The non-transitory machine-readable storage medium according to claim 12, wherein the method further comprises:
in response to the target model being located in the virtual scene, detecting, by the particle in the particle model, whether a collision occurs to the particle; and
in response to determining that the collision occurs to at least one particle in the particle model, determining that the collision event is detected.

18. The non-transitory machine-readable storage medium according to claim 12, wherein obtaining the mapping relationship between the particle and the mesh vertex comprising:
placing the target model and the particle model in a preset world coordinate system in a manner of coinciding with each other;
for the mesh vertex in the target model, determining a specified number of target particles from the particle model, establishing a local coordinate system based on the specified number of target particles, and determining a first conversion relationship between the local coordinate system and the world coordinate system;
obtaining a local rendering parameter by converting an initial rendering parameter for the mesh vertex in the world coordinate system into the local coordinate system based on the first conversion relationship, wherein the initial rendering parameter comprises more than one of a position parameter, a normal parameter, and a tangent parameter for the mesh vertex; and
determining the mesh vertex, the target particles, and the local rendering parameter as the mapping relationship between the particle and the mesh vertex.

19. The non-transitory machine-readable storage medium according to claim 18, wherein determining the specified number of target particles from the particle model, comprises:
for the mesh vertex in the target model, calculating Euclidean distances between the mesh vertex and at least part of particles in the particle model; and
obtaining a particle sequence by sorting the at least part of particles in an ascending order according to the Euclidean distances, and determining first three particles in the particle sequence as the target particles.

20. The non-transitory machine-readable storage medium according to claim 18, wherein establishing the local coordinate system based on the specified number of target particles comprises:
taking a first particle in the target particles as an origin of the local coordinate system;
taking a connecting direction between the first particle and a second particle in the target particles as a first axial direction of the local coordinate system;
taking a direction corresponding to a vector product of a connecting direction between a third particle in the target particles and the first particle and the first axial direction as a second axial direction of the local coordinate system; and
obtaining the local coordinate system by taking a direction perpendicular to both the first axial direction and the second axial direction as a third axial direction of the local coordinate system.

21. The non-transitory machine-readable storage medium according to claim 12, wherein determining the first rendering parameter for the mesh vertex in the target model based on the first position of the particle in the particle model and the mapping relationship between the particle and the mesh vertex comprises:
obtaining a specified number of target particles corresponding to the mesh vertex from the mapping relationship;
establishing a deformation coordinate system based on first positions of the specified number of target particles, and determining a second conversion relationship between the deformation coordinate system and a preset world coordinate system, wherein the world coordinate system is established in the virtual scene where the target model and the particle model are located;
obtaining a local rendering parameter corresponding to the mesh vertex from the mapping relationship; and
determining the first rendering parameter for the mesh vertex in the world coordinate system based on the second conversion relationship and the local rendering parameter.
